(19) United States
(12) Patent Application Publication
(10) Pub. No.: US 2026/0198342 A1
(43) Pub. Date: Jul. 9, 2026

(54) MULTILAYER WIRING SUBSTRATE

(71) Applicant: LG INNOTEK CO., LTD., Seoul (KR)

(72) Inventors: Sang Young LEE, Seoul (KR); Yong Jae CHOI, Seoul (KR)

(21) Appl. No.: 18/719,061

(22) PCT Filed: Nov. 25, 2022
(86) PCT No.: PCT/KR2022/018851

§ 371 Date: Feb. 27, 2026

(30) Foreign Application Priority Data
Dec. 16, 2021 (KR) 10-2021-0180548

(51) Int. Cl. H10W 70/63; H10W 70/05; H10W 70/66

(52) U.S. Cl. CPC H10W 70/63; H10W 70/095; H10W 70/66

(57) ABSTRACT

A multilayer wiring substrate according to an embodiment includes a plurality of insulating layers sequentially stacked; and a wiring pattern disposed on the insulating layer, wherein the insulating layer includes at least one via hole, a conductive layer is disposed inside the via hole, a bonding layer is disposed between the wiring pattern and the conductive layer, the bonding layer includes at least one region of a first region and a second region having a chemical formula of CuxSny, a value of x/x+y of the second region is greater than a value of x/x+y of the first region, and a volume or an area of the second region is greater than a volume or an area of the first region.

### TECHNICAL FIELD

An embodiment relates to a multilayer wiring substrate.

### BACKGROUND ART

The multilayer wiring substrate is a circuit line pattern formed of a conductive material such as copper on an insulating substrate. The multilayer wiring substrate means a board just before mounting an electronic component.

Signals generated from components mounted on the multilayer wiring substrate may be moved through a wiring pattern connected to each of the components.

Such a multilayer wiring substrate may be manufactured by thermocompression a plurality of insulating substrates on which wiring patterns are formed. That is, the multilayer wiring substrate may be formed by thermocompression a plurality of insulating layers and adhering the insulating layers.

The multilayer wiring substrate includes a via hole formed in each insulating layer to electrically connect wiring patterns disposed on different insulating layers.

The via hole is filled with a conductive material. The wiring patterns disposed on different insulating layers are electrically connected through a conductive layer formed of the conductive material.

Conventionally, a conductive layer was formed by filling the inside of the via hole with a conductive paste. Accordingly, the via hole had to have a size greater than the set width in order to fill the conductive paste. Accordingly, a size of the multilayer wiring substrate was increased.

In addition, the conductive paste contains heterogeneous materials. As a result, voids and fluxes were provided inside the conductive layer formed by curing the paste. Accordingly, the mechanical strength of the conductive layer inside the via hole was reduced by the voids and fluxes.

In addition, the conductive paste containing heterogeneous materials was thermally compressed to form a plurality of alloy layers through the reaction of the heterogeneous materials. That is, the conductive layer inside the via hole includes a plurality of alloys having different composition ratios. Accordingly, there is a problem in that the electrical and thermal characteristics of the conductive layer are reduced, and the adhesion to the wiring pattern is reduced.

Accordingly, there was a problem in that the mechanical characteristics, thermal characteristics, and electrical characteristics of the multilayer wiring substrate including the conductive layer were reduced.

Therefore, a multilayer wiring substate with a new structure capable of solving the above problems is required.

### DISCLOSURE

### Technical Problem

The embodiment provides a multilayer wiring substrate with improved electrical, mechanical, and thermal characteristics.

### Technical Solution

A multilayer wiring substrate according to an embodiment includes a plurality of insulating layers sequentially stacked; and a wiring pattern disposed on the insulating layer, wherein the insulating layer includes at least one via hole, a conductive layer is disposed inside the via hole, a bonding layer is disposed between the wiring pattern and the conductive layer, the bonding layer includes at least one region of a first region and a second region having a chemical formula of CuxSny, a value of x/x+y of the second region is greater than a value of x/x+y of the first region, and a volume or an area of the second region is greater than a volume or an area of the first region.

### Advantageous Effects

A multilayer wiring substrate according to an embodiment includes a via hole for connecting a plurality of wiring patterns, a conductive layer disposed inside the via hole, and a bonding layer between the conductive layer and the wiring pattern.

The bonding layer may include at least one alloy. In detail, the bonding layer may include at least one alloy having a chemical formula of CuxSny.

In this case, a ratio of the alloy of the bonding layer may be adjusted. In detail, the bonding layer may include a first copper-tin alloy and a second copper-tin alloy. The bonding layer may include a ratio of the first copper-tin alloy to be greater than a ratio of the second copper-tin alloy. Accordingly, thermal characteristics, electrical characteristics, mechanical characteristics, and adhesion characteristics with a metal by the bonding layer may be improved.

Therefore, the multilayer wiring substrate according to the embodiment can improve an adhesion between the wiring pattern and the conductive layer through the bonding layer. Additionally, the bonding layer can provide improved electrical, mechanical, and thermal characteristics.

Additionally, the bonding layer is disposed both inside and outside the via hole. At this time, a thickness of the bonding layer is smaller than a thickness of the conductive layer inside the via hole. That is, the conductive layer is disposed more than the bonding layer inside the via hole.

Therefore, it is possible to prevent the electrical characteristics, mechanical characteristics, and thermal characteristics inside the via hole from being reduced.

In addition, the bonding layer may be disposed inside the via hole between a side surface of the conductive layer and an inner surface of the via hole. Therefore, the bonding layer can protect the conductive layer inside the via hole. Therefore, it is possible to prevent an external impact from being directly provided to the conductive layer inside the via hole.

In addition, in the multilayer wiring substrate according to the embodiment, the conductive layer and the bonding layer may be disposed inside the via hole through a plating method and a thermocompression method. Therefore, a diameter of the via hole may be reduced compared to filling the inside of the via hole using a paste method. Therefore, an overall size of the multilayer wiring substrate may be reduced.

### DESCRIPTION OF DRAWINGS

FIG. 1 is a cross-sectional view of a multilayer wiring substrate according to an embodiment.

FIG. 2 is a view for describing a bonding process of a multilayer wiring substrate according to an embodiment.

FIG. 3 is an enlarged view of a ‘A’ region of FIG. 1.

FIGS. 4 and 5 are enlarged views of a ‘C’ region of FIG. 3.

FIG. 6 is view for describing a change in composition and composition ratio of a bonding layer of a multilayer wiring substrate according to an embodiment.

FIG. 7 is a table for describing characteristics of an alloy layer inside a bonding layer of a multilayer wiring substrate according to an embodiment.

FIGS. 8 to 11 are enlarged views of a ‘B’ region of FIG. 1.

FIG. 12 is a view illustrating an optical photograph of a bonding layer according to an embodiment.

FIGS. 13 and 14 are diagrams for describing the distribution of grain sizes of bonding layers according to examples and comparative examples, respectively.

### MODES OF THE INVENTION

Hereinafter, embodiments of the present invention will be described in detail with reference to the accompanying drawings. However, the spirit and scope of the present invention is not limited to a part of the embodiments described, and may be implemented in various other forms, and within the spirit and scope of the present invention, one or more of the elements of the embodiments may be selectively combined and replaced.

In addition, unless expressly otherwise defined and described, the terms used in the embodiments of the present invention (including technical and scientific terms) may be construed the same meaning as commonly understood by one of ordinary skill in the art to which this invention belongs, and the terms such as those defined in commonly used dictionaries may be interpreted as having a meaning that is consistent with their meaning in the context of the relevant art.

In addition, the terms used in the embodiments of the present invention are for describing the embodiments and are not intended to limit the present invention. In this specification, the singular forms may also include the plural forms unless specifically stated in the phrase, and may include at least one of all combinations that may be combined in A, B, and C when described in “at least one (or more) of A (and), B, and C”.

Further, in describing the elements of the embodiments of the present invention, the terms such as first, second, A, B, (a), and (b) may be used. These terms are only used to distinguish the elements from other elements, and the terms are not limited to the essence, order, or order of the elements.

In addition, when an element is described as being “connected”, or “coupled” to another element, it may include not only when the element is directly “connected” to, or “coupled” to other elements, but also when the element is “connected”, or “coupled” by another element between the element and other elements.

Further, when described as being formed or disposed “on (over)” or “under (below)” of each element, the “on (over)” or “under (below)” may include not only when two elements are directly connected to each other, but also when one or more other elements are formed or disposed between two elements.

Furthermore, when expressed as “on (over)” or “under (below)”, it may include not only the upper direction but also the lower direction based on one element.

Hereinafter, a multilayer wiring substrate according to embodiments will be described with reference to the drawings. The multilayer wiring substrate described below may include a rigid multilayer wiring substrate or a flexible multilayer wiring substrate. In addition, the multilayer wiring substrate may be an antenna substrate.

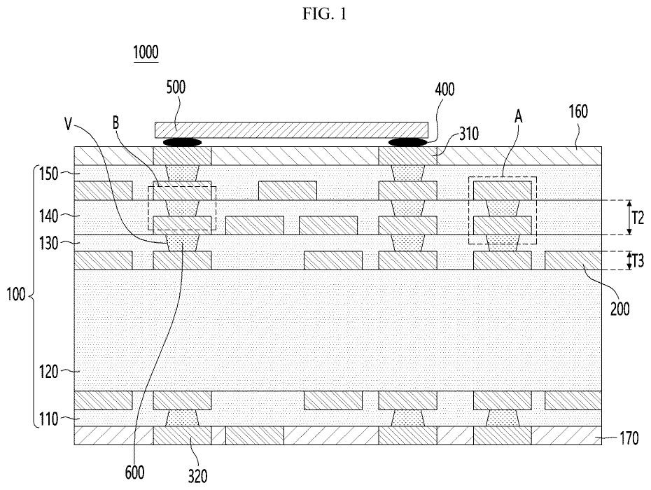

Referring to FIG. 1, a multilayer wiring substrate 1000 according to an embodiment includes an insulating layer 100 and a wiring pattern 200.

The insulating layer 100 includes an insulating material. That is, the insulating layer 100 is an insulating substrate that does not have conductivity.

The insulating layer 100 supports the wiring pattern 200. In detail, the wiring pattern 200 is disposed on at least one of one surface and the other surface of the insulating layer 100. That is, the insulating layer 100 is a support substrate supporting the wiring pattern 200.

The multilayer wiring substrate 1000 includes a plurality of insulating layers 100. For example, the multilayer wiring substrate 1000 may include a first insulating layer 110, a second insulating layer 120 disposed on the first insulating layer 110, a third insulating layer 130 disposed on the second insulating layer 120, a fourth insulating layer 140 disposed on the third insulating layer 130, and a fifth insulating layer 150 on the fourth insulating layer 140.

However, the embodiment is not limited thereto. That is, the multilayer wiring substrate 1000 may include less than five insulating layers. Alternatively, the multilayer wiring substrate 1000 may include more than five insulating layers. Hereinafter, for convenience of explanation, it will be described that the multilayer wiring substrate 1000 includes the first insulating layer 110, the second 120, the third insulating layer 130, the fourth insulating layer 140, and the fifth insulating layer 150.

The first insulating layer 110, the second insulating layer 120, the third insulating layer 130, the fourth insulating layer 140, and the fifth insulating layer 150 are sequentially stacked and disposed.

The insulating layer 100 may have a partially curved surface and be bent. That is, the insulating layer 100 may partially have a plane and may partially be bent having a curved surface. In detail, an end of the insulating layer 100 may be bent having a curved surface. Alternatively, the insulating layer 100 may be bent while having a surface including a random curvature.

In addition, the insulating layer 100 may be a flexible insulating layer. In addition, the insulating layer 100 may be a curved or bended substrate.

That is, the multilayer wiring substrate including the insulating layer 100 may include a flexible multilayer wiring substrate.

The insulating layer 100 may include a resin material. For example, the insulating layer 100 may include a resin material whose physical characteristics change depending on temperature. In detail, the insulating layer 100 includes a thermoplastic resin.

For example, the insulating layer 100 may include a liquid crystal polymer.

The liquid crystal polymer material is a material having characteristics of both a liquid state and a solid state. That is, the liquid crystal polymer material has a regular crystal orientation like a solid state even in a liquid state.

Therefore, since the insulating layer 100 includes the liquid crystal polymer, the heat resistance of the multilayer wiring substrate can be improved. Additionally, signal loss depending on a dielectric constant of the material can be reduced, thereby improving signal transmission characteristics of the multilayer wiring substrate.

The insulating layer 100 has a thickness within a set range. In detail, the insulating layer 100 may have a thickness of 150 μm or less, a thickness of 25 μm to 150 μm, or a thickness of 50 μm to 100 μm.

When the thickness T2 of the insulating layer 100 is less than 25 um, it is difficult for the insulating layer 100 to sufficiently support the wiring pattern 200, and an overall strength of the multilayer wiring substrate may be reduced. In addition, when the thickness of the insulating layer 100 is more than 150 um, a time of a process of forming the via hole V can be increased and an overall size of the multilayer wiring substrate can be increased due to the increase in the thickness of the insulating layer 100.

The wiring pattern 200 is disposed on the insulating layer 100. In detail, the wiring pattern 200 is disposed on at least one of one surface and the other surface of the insulating layer 100.

The wiring pattern 200 may be in direct contact with the insulating layer 100. That is, no separate bonding layer is disposed between the insulating layer 100 and the wiring pattern 200. Accordingly, an overall thickness of the multilayer wiring substrate 1000 is reduced.

The wiring pattern 200 is a path for transmitting electrical signals of the multilayer wiring substrate 1000. That is, the multilayer wiring substrate 1000 can transmit an electric signal to another member connected to the multilayer wiring substrate 1000 through the wiring pattern 200. Alternatively, the multilayer wiring substrate 1000 may receive electrical signals generated from the other members through the wiring pattern 200.

Accordingly, the wiring pattern 200 may include a highly conductive material. In detail, the wiring pattern 200 may include a metal. For example, the wiring pattern 200 may include at least one metal of gold (Au), silver (Ag), platinum (Pt), titanium (Ti), tin (Sn), copper (Cu), zinc (Zn), and alloys thereof. Preferably, the wiring pattern 200 includes copper (Cu). In other words, the wiring pattern 200 is copper (Cu).

The wiring pattern above 200 may be disposed on the insulating layer 100 through an Additive process, a Subtractive process, a Modified Semi Additive Process (MSAP), or a Semi Additive Process (SAP) process, which are typical manufacturing processes of a printing multilayer wiring substrate.

The wiring pattern 200 has a line width and thickness within a set range. In detail, the wiring pattern 200 may have a line width of 40 um to 150 um. In more detail, the wiring pattern 200 may have a line width of 70 um to 120 um.

When the line width of the wiring pattern 200 is less than 40 um, process efficiency may decrease. Additionally, when the line width of the wiring pattern 200 exceeds 150 um, a size of the multilayer wiring substrate may be increased.

Additionally, the wiring pattern 200 may have a thickness of 15 um or less. In more detail, the wiring pattern 200 may have a thickness of 10 um to 15 um. In more detail, the wiring pattern 200 may have a thickness of 11 um to 14 um.

When the thickness T3 of the wiring pattern 200 is less than 10 um, the electrical characteristics of the wiring pattern 200 may be reduced. Additionally, when the thickness of the wiring pattern 200 is greater than 15 um, a size of the multilayer wiring substrate may be increased.

The insulating layer 100 includes at least one via hole V. In detail, at least one of the first insulating layer 110, the second insulating layer 120, the third insulating layer 130, the fourth insulating layer 140, and the fifth insulating layer 150 may include at least one via hole V.

The via hole V is formed penetrating the insulating layer 100. Additionally, a conductive layer 600 is disposed inside the via hole V. In detail, a conductive layer 600 containing a conductive material is disposed inside the via hole V. Wiring patterns disposed on different insulating layers are electrically connected through the via hole V and the conductive layer 600.

The conductive layer 600 includes a conductive material. Specifically, the conductive layer 600 includes a metal. For example, the conductive layer 600 may include at least one metal among copper (Cu), silver (Ag), tin (Sn), gold (Au), nickel (Ni), palladium (Pd), and alloys thereof. Preferably, the conductive layer 600 includes copper (Cu). That is, the conductive layer 600 is copper (Cu).

The conductive layer 600 may be disposed inside the via hole V by using electroless plating, electroplating, screen printing, sputtering, or evaporation. Preferably, the conductive layer 600 is disposed inside the via hole V by electroless plating or electroplating.

Pad parts are disposed on upper and lower portions of the multilayer wiring substrate 1000, respectively. In detail, a first pad part 310 is disposed on the multilayer wiring substrate 1000. Additionally, a second pad part 320 is disposed below the multilayer wiring substrate 1000.

For example, the first pad part 310 is disposed on the fifth insulating layer 150, which is an uppermost insulating layer of the multilayer wiring substrate 1000. At least one first pad part 310 may be disposed on the fifth insulating layer 150. At least one of the first pad parts 310 may serve as a pattern for signal transmission. Additionally, at least one other first pad part may serve as an inner lead for connection to an electronic component 500 connected to the multilayer wiring substrate 1000.

In addition, the second pad part 320 may be disposed below the first insulating layer 110, which is a lowermost insulating layer of the multilayer wiring substrate 1000. At least one of the second pad parts 320 may serve as a pattern for signal transmission. In addition, at least one other second pad part among the second pad parts 320 may serve as an outer lead for connection to an external substrate.

In addition, protective layers 160 and 170 are disposed on the uppermost and lowermost insulating layers of the multilayer wiring substrate 1000, respectively.

Meanwhile, the electronic component 500 connected to the multilayer wiring substrate 1000 may include both devices and chips. In conclusion, the electronic component 5000 includes a semiconductor chip, a light emitting diode chip, and other driving chips.

As previously described, the multilayer wiring substrate 1000 is formed by stacking a plurality of insulating layers forming a wiring pattern. In detail, the insulating layers are bonded through thermocompression in a set temperature range. In detail, the plurality of insulating layers 110, 120, 130, 140, and 150 are bonded to each other through a thermocompression process at a temperature in a set range.

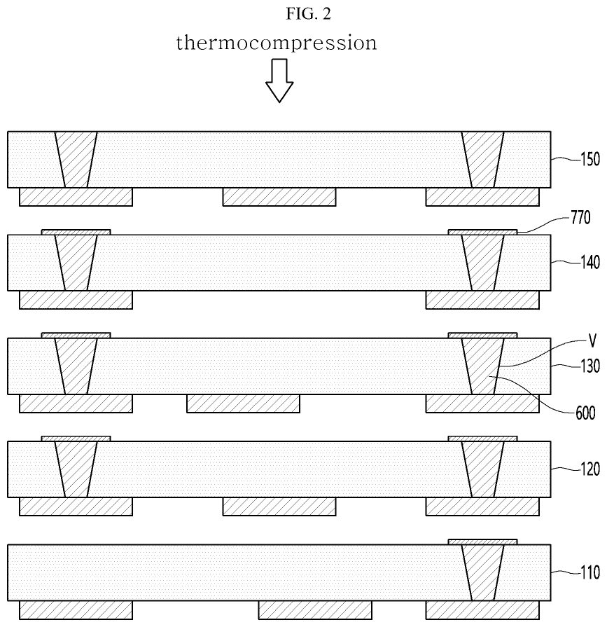

For example, referring to FIG. 2, a wiring pattern 200 and a via hole V are formed in each of the plurality of insulating layers 110, 120, 130, 140, and 150. Additionally, a conductive layer 600 is disposed inside the via hole V. Additionally, the plurality of insulating layers 110, 120, 130, 140, and 150 in which the wiring pattern 200 and the via holes V are formed may be bonded to each other through a thermocompression process in a set temperature range.

The conductive layer 600 may be formed simultaneously with a process of forming the wiring pattern 200. That is, the conductive layer 600 is disposed inside the via hole through a plating process.

The thermocompression process may be performed at a temperature higher than melting points of the insulating layers 110, 120, 130, 140, and 150. That is, the insulating layers 110, 120, 130, 140, and 150 are melted at a temperature higher than the melting point of the insulating layers 110, 120, 130, 140, and 150. Subsequently, the molten insulating layers 110, 120, 130, 140, and 150 are adhered to each other.

At this time, the wiring patterns 200 disposed on different insulating layers are electrically connected through the conductive layer 600 inside the via hole V. That is, a region in which the via hole V is formed on the plurality of insulating layers 110, 120, 130, 140, and 150 is a region in which a metal material of the wiring pattern 200 and a metal material of the conductive layer 600 are bonded, unlike other regions.

However, the melting point of the metal material of the wiring pattern 200 is greater than the melting point of the insulating layer. Accordingly, when the conductive layer 600 and the wiring pattern 200 include the same copper metal, the conductive layer 600 and the wiring pattern 200 do not melt at the melting temperature of the insulating layer. Accordingly, the conductive layer 600 and the wiring pattern 200 may not be adhered or bonded to each other.

Accordingly, a bonding material 770 may be disposed between the conductive layer 600 and the wiring pattern 200. The bonding material 770 is disposed on the conductive layer 600 through a plating process.

The bonding material 770 includes a metal material having a melting point lower than that of the wiring pattern 200 and the conductive layer 600. Therefore, even if the thermocompression process is performed at a temperature close to the melting point of the insulating layer, the conductive layer inside the via hole and wiring pattern can be bonded through the bonding material 770.

Meanwhile, when the bonding material 770 is melted, an alloy may be formed by reacting a metal material of the bonding material 770, a metal material of the wiring pattern 200, and a metal material of the conductive layer 600.

These alloys can have various electrical, thermal, and mechanical characteristics depending on their composition. Accordingly, the adhesive characteristics of the conductive layer and the wiring pattern, and the electrical characteristics, thermal characteristics, and mechanical characteristics of the multilayer wiring substrate vary depending on the composition of the alloy.

Therefore, hereinafter, a multilayer wiring substrate having improved electrical, thermal, and mechanical characteristics by adjusting a composition ratio of the bonding layer formed by the bonding material 770 between the conductive layer 600 and the wiring pattern 200 will be described.

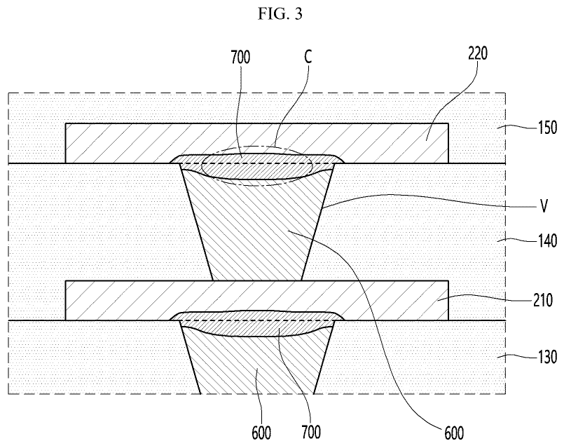

FIG. 3 is an enlarged view of a ‘A’ region of FIG. 1. That is, FIG. 3 is an enlarged view of a region in which via holes of the multilayer wiring substrate are formed.

Referring to FIG. 3, a conductive layer 600 is disposed inside the insulating layer 100. In detail, a plurality of via holes V are formed in the insulating layer 100, and the conductive layer 600 is disposed inside the via holes V.

Based on the fourth insulating layer 140, wiring patterns 200 are disposed on the upper and lower surfaces of the conductive layer 600, respectively. For example, a first wiring pattern 210 is disposed on the lower surface of the conductive layer 600, and a second wiring pattern 220 is disposed on the upper surface of the conductive layer 600. The first wiring pattern 210 is a wiring pattern disposed on the third insulating layer 130, and the second wiring pattern 220 is a wiring pattern disposed on the fourth insulating layer 140.

The first wiring pattern 210 and the second wiring pattern 220 disposed on different insulating layers are electrically connected through a conductive layer 600 disposed inside the via hole V.

The conductive layer 600 and the first wiring pattern 210 are formed simultaneously through the same process. That is, the conductive layer 600 inside the via hole V and the first wiring pattern 210 disposed on the fourth insulating layer 140 are formed simultaneously through a plating process. Accordingly, the conductive layer 600 and the first wiring pattern 210 are formed integrally.

A bonding layer 700 is disposed between the conductive layer 600 and the second wiring pattern 220 on the fifth insulating layer 150. In detail, a bonding layer 700 formed by the bonding material 770 is disposed between the conductive layer 600 inside the via hole V and the second wiring pattern 220.

The bonding layer 700 is disposed on an upper portion of the via hole V. In detail, the bonding layer 700 is disposed on the upper portion of the via hole V with a large diameter.

The wiring pattern 210 and 220, the conductive layer 600, and the bonding layer 700 may include different materials. In detail, the wiring pattern 210 and 220, the conductive layer 600, and the bonding layer 700 may include different metal materials.

For example, the wiring patterns 210 and 220 and the conductive layer 600 include the same metal material. Additionally, the bonding layer 700 includes a metal material different from that of at least one of the wiring pattern 210 and the conductive layer 600.

The bonding layer 700 includes a first region 1A and a second region 2A. In detail, the bonding layer 700 includes a first region 1A and a second region 2A forming a boundary in a depth direction of the via hole V. The second region 2A is disposed on and under the first region 1A. Accordingly, the first region 1A is disposed between the second regions 2A.

The second region 2A is disposed closer to the wiring pattern 200 than the first region 1A. Additionally, the second region 2A is disposed between the first region 1A and the wiring pattern 200.

An alloy is disposed in the first region 1A and the second region 2A of the bonding layer 700. In detail, an alloy having the same composition is disposed in the first region 1A and the second region 2A of the bonding layer 700. Additionally, an alloy having the same composition ratio is disposed in the first region 1A and the second region 2A of the bonding layer 700. In addition, alloys having different composition ratios are disposed in the first region 1A and the second region 2A of the bonding layer 700.

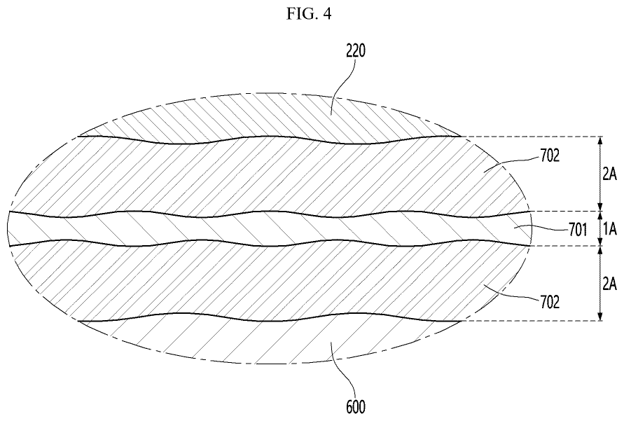

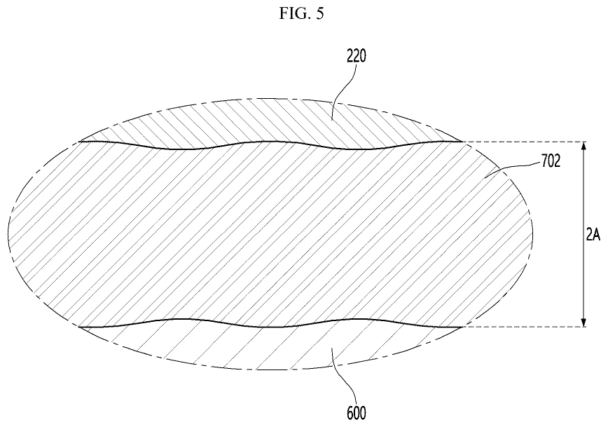

FIGS. 4 and 5 are enlarged views of the bonding layer.

Referring to FIG. 4, the bonding layer 700 is defined by a first region 1A and a second region 2A. An alloy is disposed in the first region 1A and the second region 2A, respectively. In detail, alloys having the same composition and different composition ratios are disposed in the first region 1A and the second region 2A. For example, a first alloy 701 is disposed in the first region 1A, and a second alloy 702 is disposed in the second region 2A.

For example, an alloy having a chemical formula of CuxSny is disposed in the first region 1A and the second region 2A. At this time, x+y satisfies 0<x+y<12, or x+y satisfies 4≤x+y≤11.

That is, a first copper-tin alloy is disposed in the first region 1A. Additionally, a second copper-tin alloy is disposed in the second region 2A. The first copper-tin alloy and the second copper-tin alloy have different composition ratios. In detail, a value of x/x+y of the second copper-tin alloy is greater than a value of x/x+y of the first copper-tin alloy. In other words, a copper ratio of the second copper-tin alloy is greater than a copper ratio of the first copper-tin alloy.

For example, the first copper-tin alloy has a chemical formula of Cu₆Sn₅, and the second copper-tin alloy has a chemical formula of Cu₃Sn₁. That is, the first copper-tin alloy having the chemical formula of Cu₆Sn₅ is disposed in the first region 1A, and the second copper-tin alloy having the chemical formula of Cu₃Sn₁ is disposed in the second region 2A.

Therefore, the second copper-tin alloy having the chemical formula of Cu₃Sn₁ is disposed in a region close to the wiring pattern 200, and the first copper-tin alloy having the chemical formula of Cu₆Sn₅ is disposed in a region far from the wiring pattern 200.

Accordingly, an amount of copper in the bonding layer 700 increases from the first region 1A toward the second region OA. Also, an amount of tin in the bonding layer 700 increases from the second region 2A toward the first region 1A.

The first region 1A and the second region 2A are provided in different sizes. For example, the first region 1A and the second region 2A are provided in different volumes. Alternatively, the first region 1A and the second region 2A are provided in different areas.

In detail, the volume or area of the second region 2A is larger than the volume or area of the first region 1A.

In detail, when an entire volume of the first region 1A and the second region 2A is set to 100%, a volume of the second region 2A is larger than a volume of the first region 1A. For example, the second region 2A may have a volume exceeding 50%. More specifically, the second region 2A may have a volume of 50% to less than 100%. Preferably, the second region 2A has a volume of 90% or more. More preferably, the second region 2A has a volume of 95% or more.

Additionally, the first region 1A may have a volume of less than 50%. More specifically, the first region 1A may have a volume of more than 0% and less than 50%. Preferably, the first region 1A has a volume of 10% or less. More preferably, the first region 1A has a volume of 5% or less.

Alternatively, when the entire area of the first region 1A and the second region 2A is set to 100%, the area of the second region 2A is larger than the area of the first region 1A. For example, the second region 2A may have an area of more than 50%. More specifically, the second region 2A may have an area of 50% to less than 100%. Preferably, the second region 2A has an area of 90% or more. More preferably, the second region 2A has an area of 95% or more.

Additionally, the first region 1A may have an area of less than 50%. In more detail, the first region 1A may have an area of more than 0% and less than 50%. Preferably, the first region 1A has an area of 10% or less. More preferably, the first region 1A has an area of 5% or less.

Meanwhile, referring to FIG. 5, the bonding layer 700 may include only one region. In detail, the bonding layer 700 may include one region in which an alloy having a single composition and composition ratio is disposed. That is, the bonding layer 700 includes only the second region 2A described above.

That is, the bonding layer 700 includes only the second alloy 702 having the chemical formula of CuxSny. That is, the bonding layer 700 includes only the second copper-tin alloy having the chemical formula of Cu₃Sn₁.

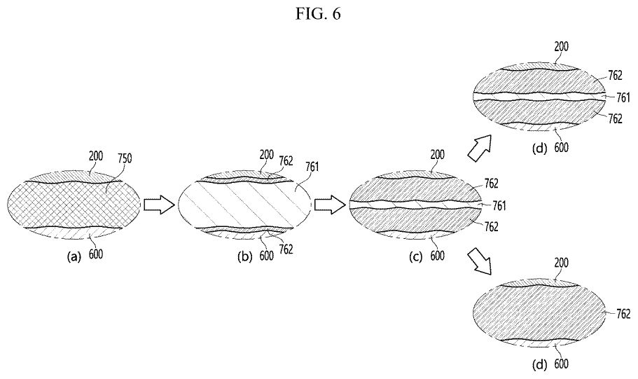

FIG. 6 is view for describing a change in composition and composition ratio of a bonding layer.

Referring to FIG. 6(a), the bonding layer 700 before thermocompression of the plurality of insulating layers includes a metal having a single composition. For example, the bonding layer 700 before the thermocompression includes a first metal layer 750. For example, the first metal layer 750 is tin (Sn).

FIG. 6(b) to 6(d) are views for describing changes in the composition and composition ratio of the bonding layer 700 during the thermocompression process.

Referring to FIG. 6(b), the composition and composition ratio of the first metal layer 750 may be variously changed in an initial stage of the thermocompression process. Specifically, the first metal layer 750 reacts with the wiring pattern 200 and the conductive layer 600 to form a plurality of alloys. Accordingly, the bonding layer 700 may include the first metal layer 750 and a plurality of alloys.

In detail, a first alloy layer 761 and a second alloy layer 762 having the chemical formula of CuxSny are formed in a region between the first metal layer 750 and the wiring pattern 200 and a region between the first metal layer 750 and the conductive layer 600. In more detail, the first alloy layer 761 is formed between the second alloy layers 762. Additionally, the second alloy layer 762 is formed in a region between the first alloy layer 761 and the wiring pattern 200 and in a region between the first alloy layer 761 and the conductive layer 600.

The first alloy layer 761 and the second alloy layer 762 have the same composition. Additionally, the first alloy layer 761 and the second alloy layer 762 have different composition ratios. For example, the x value and y value of the first alloy layer 761 are different from that of the second alloy layer 762.

For example, the first alloy layer 761 may have the chemical formula of Cu₆Sn5=, and the second alloy layer 762 may have the chemical formula of Cu₃Sn₁.

Additionally, the sizes of the first alloy layer 761 and the second alloy layer 762 may be different. In detail, the volume or area of the first alloy layer 761 is larger than the volume or area of the second alloy layer 762.

Next, referring to FIG. 6(c), the sizes of the first alloy layer 761 and the second alloy layer 762 change during the thermocompression process.

In detail, referring to FIG. 6(c), an amount of copper diffused into the bonding layer 700 increases during the thermocompression process. As a result, the volume or area of the second alloy layer 762 may be greater than or equal to the volume or area of the first alloy layer 761.

Next, referring to FIG. 6(d), the sizes of the first alloy layer 761 and the second alloy layer 762 change in an end stage of the thermocompression process.

In detail, referring to FIG. 6(d), the amount of copper diffused into the bonding layer 700 increases in the end stage of the thermocompression process. As a result, the volume or area of the second alloy layer 762 becomes larger than the volume or area of the first alloy layer 761.

That is, the volume or area of the second alloy layer 762 changes to become larger than the volume or area of the first alloy layer 761.

Accordingly, the bonding layer 700 may be changed so that the volume or area of the second alloy layer 762 is larger than the volume or area of the first alloy layer 761. Alternatively, the bonding layer 700 may be changed to include only the second alloy layer 762.

That is, the first alloy layer 761 and the second alloy layer 762 may correspond to the first alloy 701 and the second alloy 702 of FIG. 4 described above, respectively.

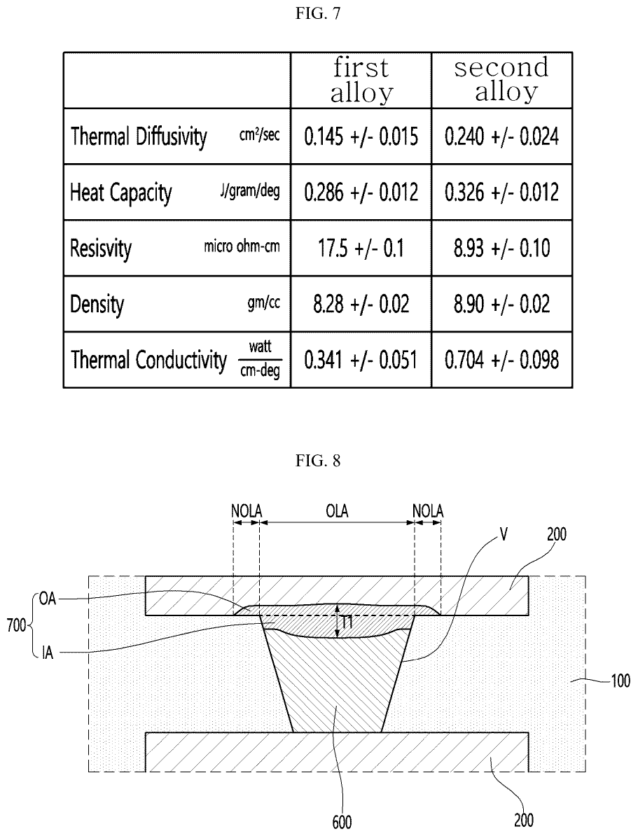

FIG. 7 is a table for explaining the characteristics of alloy layers having different compositions.

Referring to FIG. 7, the first alloy 701 and the second alloy 702 disposed in the first region 1A and the second region 2A of the bonding layer 700 have different physical characteristics. That is, the first alloy 701 and the second alloy 702 have different composition ratios and thus different physical characteristics.

In detail, a thermal diffusivity of the second alloy 702 is greater than that of the first alloy 701. Additionally, ae heat capacity of the second alloy 702 is greater than that of the first alloy 701. Additionally, a thermal conductivity of the second alloy 702 is greater than that of the first alloy 701.

Accordingly, the second region 2A has improved thermal characteristics compared to the first region 1A. That is, in the bonding layer 700, the ratio of the second region 2A is larger than the ratio of the first region 1A, thereby improving thermal characteristics. Accordingly, the multilayer wiring substrate 100 including the bonding layer 700 has improved thermal characteristics.

Additionally, a density of the second alloy 702 is greater than a density of the first alloy 701. Accordingly, the second region 2A has improved strength compared to the first region 1A. That is, the second region 2A has improved mechanical characteristics compared to the first region 1A. Accordingly, in the bonding layer 700, the ratio of the second region 2A is larger than the ratio of the first region 1A, thereby improving thermal characteristics, thereby improving mechanical characteristics. Accordingly, the multilayer wiring substrate 100 including the bonding layer 700 has improved mechanical characteristics.

Additionally, a resistance of the second alloy 702 is smaller than that of the first alloy 701. Accordingly, the second region 2A has improved electrical characteristics compared to the first region 1A. That is, in the bonding layer 700, the ratio of the second region 2A is larger than the ratio of the first region 1A, thereby improving electrical characteristics. Accordingly, the multilayer wiring substrate 100 including the bonding layer 700 has improved electrical characteristics.

Hereinafter, with reference to FIGS. 8 to 11, an arrangement of the bonding layer of the multilayer wiring substrate according to the embodiment will be described in detail.

Referring to FIGS. 8 to 10, the bonding layer 700 is disposed between the wiring pattern 200 and the conductive layer 600.

Specifically, the bonding layer 700 includes an overlapping region OLA that overlaps the via hole V in a longitudinal direction of the via hole V and a non-overlapping region NOLA that does not overlap the via hole in the longitudinal direction. More specifically, the bonding layer 700 includes a contact region CA in contact with the conductive layer 600 and a non-contact region NCA not in contact with the conductive layer 700.

A thickness of the bonding layer 700 is different from a thickness of the insulating layer 100. Additionally, the thickness of the bonding layer 700 is different from a thickness of the wiring pattern 700. Additionally, the thickness of the bonding layer 700 is different from a thickness of the conductive layer 600.

In detail, the thickness T1 of the bonding layer 700 is smaller than the thickness of the insulating layer 100. Additionally, the thickness T1 of the bonding layer 700 is smaller than the thickness of the wiring pattern 200. Here, the thickness T1 of the bonding layer 700 is defined as a maximum thickness of the bonding layer.

For example, the thickness T1 of the bonding layer 700 may be 1% to 20% of the thickness of the insulating layer 100. Additionally, the thickness T1 of the bonding layer 700 may be 5% to 25% of the thickness of the wiring pattern 200.

For example, the thickness T1 of the bonding layer 700 may be 1 μm or more. In detail, the thickness T1 of the bonding layer 700 may be 1 um to 4 um. In more detail, the thickness T1 of the bonding layer 700 may be 1 um to 3 um. In more detail, the thickness T1 of the bonding layer 700 may be 1.5 um to 2 um.

When the thickness T1 of the bonding layer 700 is less than 1 um, a void may be formed inside the bonding layer 700 due to a surface roughness formed at a surface of the bonding layer 700. As a result, the reliability of the bonding layer 700 may be deteriorated.

Additionally, when the thickness T1 of the bonding layer 700 is less than 1 um, the adhesive force between the wiring pattern 700 and the bonding layer 700 may be deteriorated.

The bonding layer 700 is disposed inside the via hole V. Additionally, the bonding layer 700 is disposed outside the via hole V. That is, the bonding layer 700 is disposed both inside and outside the via hole V.

Referring to FIGS. 8 to 10, the bonding layer 700 includes an inner region IA disposed inside the via hole V and an outer region OA disposed outside the via hole V. The inner region IA is disposed inside the via hole V and in contact with the conductive layer 600. Additionally, the outer region OA is disposed outside the via hole V and in contact with the wiring pattern 200.

The inner region IA and the outer region OA may be provided to have different thicknesses. For example, as shown in FIG. 8, a thickness of the inner region IA may be greater than a thickness of the outer region OA. In detail, the thickness of the bonding layer 700 disposed inside the via hole V may be greater than the thickness disposed outside the via hole V.

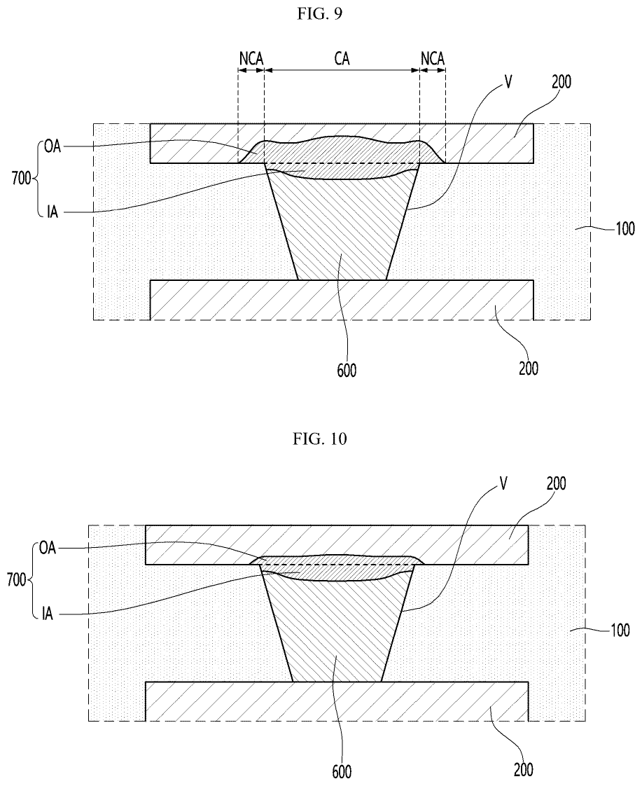

Alternatively, as shown in FIG. 9, the thickness of the inner region IA may be smaller than the thickness of the outer region OA. In detail, the thickness of the bonding layer 700 disposed inside the via hole V may be smaller than the thickness disposed outside the via hole V.

Alternatively, the inner region IA and the outer region OA may be arranged to have the same or similar thickness. For example, as shown in FIG. 10, the thickness of the inner region IA and the thickness of the outer region OA may be the same within a tolerance range. In detail, the thickness of the bonding layer 700 disposed inside the via hole V and the thickness disposed outside the via hole V may be the same within a tolerance range.

Since the bonding layer 700 is also disposed inside the via hole V, two layers can be disposed inside the via hole V. That is, the conductive layer 600 and the bonding layer 700 are disposed inside the via hole V.

In detail, the thickness of the conductive layer 600 inside the via hole V is greater than the thickness of the bonding layer 700 inside the via hole V. In detail, the thickness of the conductive layer 600 inside the via hole V is greater than the thickness of the bonding layer 700. In more detail, the thickness of the bonding layer 700 inside the via hole V is 3% to 10% of the thickness of the conductive layer 600.

Accordingly, more conductive layers 600, which have relatively higher electrical conductivity and higher thermal conductivity, are disposed inside the via hole V than the bonding layer 700. Accordingly, the heat dissipation effect and the connection characteristics of the wiring patterns can be improved through the conductive layer 600 of the via hole V.

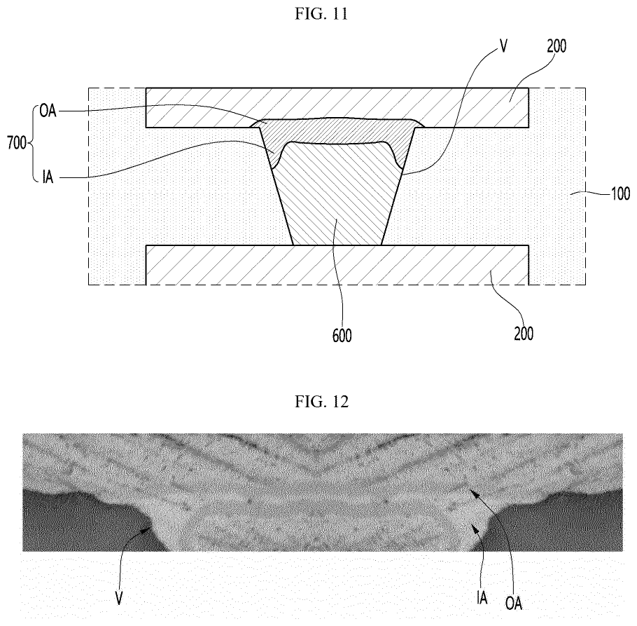

Referring to FIGS. 11 and 12, the bonding layer 700 may be disposed on a side surface of the conductive layer 600. In detail, the bonding layer 700 may be disposed in contact with the side surface of the conductive layer 600. In more detail, the bonding layer 700 may be disposed between the side surface of the conductive layer 600 and the inner surface of the via hole V.

The bonding layer 700 is melted by a process of thermally compressing the insulating layer 100. The melted bonding layer 700 can be moved between the side surface of the conductive layer 600 and the inner surface of the via hole V. Accordingly, the bonding layer 700 may also be disposed between the side surface of the conductive layer 600 and the inner surface of the via hole V.

Accordingly, damage to the conductive layer 600 inside the via hole V can be prevented. That is, an additional layer is further disposed between the side surface of the conductive layer 600 and the inner surface of the via hole V. Accordingly, it is possible to prevent external impact from being directly provided to the conductive layer 600 inside the via hole V. That is, the bonding layer 700 can serve as a buffer layer that protects the conductive layer 600.

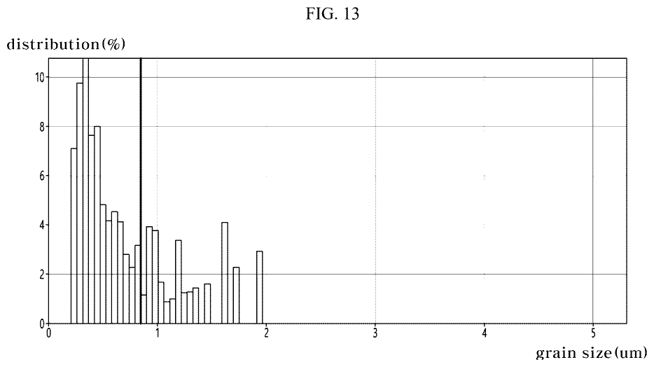

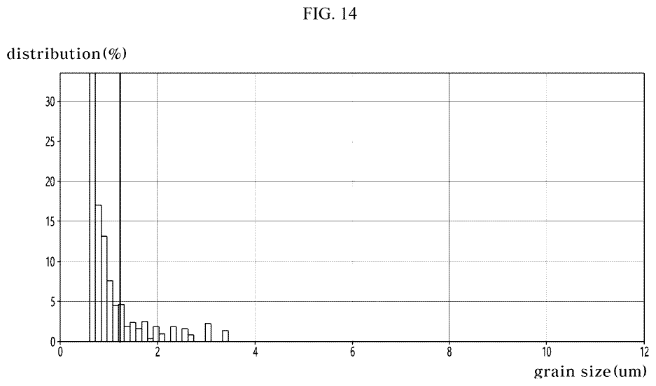

FIGS. 13 and 14 are diagrams for describing the distribution of grain sizes of bonding layers according to examples and comparative examples, respectively. In detail, FIG. 13 is a graph showing a grain size distribution of the bonding layer described above, and FIG. 14 is a graph showing a grain size distribution of a conductive layer cured by filling the inside of the via hole with a copper-tin paste.

Referring to FIGS. 13 and 14, it can be seen that the grain size of the bonding layer formed by plating the bonding material and the thermocompression process is different from the grain size of the conductive layer formed by filling the inside of the via hole with the copper-tin paste.

That is, referring to FIG. 13, it can be seen that the bonding layer according to the embodiment has a very wide distribution of grain sizes. On the other hand, referring to FIG. 14, it can be seen that the conductive layer according to the comparative example has a very narrow grain size distribution.

That is, it can be seen that the bonding layer according to the embodiment has a grain size distribution similar to the conductive layer of copper metal disposed inside the via hole.

A multilayer wiring substrate according to an embodiment includes a via hole for connecting a plurality of wiring patterns, a conductive layer disposed inside the via hole, and a bonding layer between the conductive layer and the wiring pattern.

The bonding layer may include at least one alloy. In detail, the bonding layer may include at least one alloy having a chemical formula of CuxSny.

In this case, a ratio of the alloy of the bonding layer may be adjusted. In detail, the bonding layer may include a first copper-tin alloy and a second copper-tin alloy. The bonding layer may include a ratio of the first copper-tin alloy to be greater than a ratio of the second copper-tin alloy. Accordingly, thermal characteristics, electrical characteristics, mechanical characteristics, and adhesion characteristics with a metal by the bonding layer may be improved.

Therefore, the multilayer wiring substrate according to the embodiment can improve an adhesion between the wiring pattern and the conductive layer through the bonding layer. Additionally, the bonding layer can provide improved electrical, mechanical, and thermal characteristics.

Additionally, the bonding layer is disposed both inside and outside the via hole. At this time, a thickness of the bonding layer is smaller than a thickness of the conductive layer inside the via hole. That is, the conductive layer is disposed more than the bonding layer inside the via hole.

Therefore, it is possible to prevent the electrical characteristics, mechanical characteristics, and thermal characteristics inside the via hole from being reduced.

In addition, the bonding layer may be disposed inside the via hole between a side surface of the conductive layer and an inner surface of the via hole. Therefore, the bonding layer can protect the conductive layer inside the via hole. Therefore, it is possible to prevent an external impact from being directly provided to the conductive layer inside the via hole.

In addition, in the multilayer wiring substrate according to the embodiment, the conductive layer and the bonding layer may be disposed inside the via hole through a plating method and a thermocompression method. Therefore, a diameter of the via hole may be reduced compared to filling the inside of the via hole using a paste method. Therefore, an overall size of the multilayer wiring substrate may be reduced.

The characteristics, structures, effects, and the like described in the above-described embodiments are included in at least one embodiment of the present invention, but are not limited to only one embodiment. Furthermore, the characteristic, structure, and effect illustrated in each embodiment may be combined or modified for other embodiments by a person skilled in the art. Accordingly, it is to be understood that such combination and modification are included in the scope of the present invention.

In addition, embodiments are mostly described above, but the embodiments are merely examples and do not limit the present invention, and a person skilled in the art may appreciate that several variations and applications not presented above may be made without departing from the essential characteristic of embodiments. For example, each component specifically represented in the embodiments may be varied. In addition, it should be construed that differences related to such a variation and such an application are included in the scope of the present invention defined in the following claims,

1. A multilayer wiring substrate comprising:
an insulating layer;
a wiring pattern disposed on the insulating layer;
a conductive layer disposed in a via hole passing through at least a portion of the insulating layer along a vertical direction; and
a bonding layer disposed between the wiring pattern and the conductive layer,
wherein the bonding layer includes a material having a chemical formula of CuxSny,
wherein the bonding layer includes first and second regions in which x and y of the chemical formula have different values along the vertical direction;
wherein a value of x/x+y of the second region is greater than a value of x/x+y of the first region, and
wherein at least one of a volume, an area, and a thickness in the vertical direction of the second region is greater than at least one of a volume, an area, and a thickness in the vertical direction of the first region.

2. The multilayer wiring substrate of claim 1, wherein the bonding layer includes a first layer disposed in the first region and a second layer disposed in the second region,
wherein the first layer is a first copper-tin alloy having a chemical formula of Cu₆Sn₅, and
wherein the second layer is a second copper-tin alloy with a chemical formula of Cu₃Sn₁.

3. The multilayer wiring substrate of claim 1, wherein the second region is disposed closer to the wiring pattern than is the first region.

4. The multilayer wiring substrate of claim 1, wherein the bonding layer includes an overlapping region overlapping the via hole in the vertical direction and a non-overlapping region not overlapping the via hole in the vertical direction.

5. The multilayer wiring substrate of claim 1, wherein the bonding layer includes a contact region in contact with the conductive layer and a non-contact region that does not contact the conductive layer.

6. The multilayer wiring substrate of claim 1, wherein the bonding layer includes an inner region disposed inside the via hole and an outer region disposed outside the via hole.

7. The multilayer wiring substrate of claim 6, wherein a thickness in the vertical direction of the inner region is smaller than a thickness in the vertical direction of the conductive layer.

8. The multilayer wiring substrate of claim 1, wherein a thickness of the bonding layer is 1 um to 4 um.

9. The multilayer wiring substrate of claim 1, wherein at least a portion of the bonding layer is disposed between a side surface of the conductive layer and an inner surface of the via hole.

10. The multilayer wiring substrate of claim 1, wherein the insulating layer includes a liquid crystal polymer.

11. The multilayer wiring substrate of claim 1, wherein the wiring pattern and the conductive layer include copper (Cu).

12. The multilayer wiring substrate of claim 1,
wherein the insulating layer includes a plurality of insulating layers stacked along the vertical direction,
wherein the conductive layer includes a plurality of conductive layers provided in a plurality of via holes provided in the plurality of insulating layers,
wherein the wiring pattern includes a plurality of wiring patterns disposed on the plurality of conductive layers,
wherein the bonding layer includes a plurality of bonding layers disposed between the plurality of conductive layers and the plurality of wiring patterns,
wherein at least one of the plurality of bonding layers includes only a second region, and
wherein the second region includes a second copper-tin alloy having a chemical formula of Cu₃Sn₁.

13. The multilayer wiring substrate of claim 1, wherein melting points of the wiring pattern and the conductive layer are greater than a melting point of the insulating layer.

14. The multilayer wiring substrate of claim 13, wherein the bonding layer includes a bonding material having a melting point lower than that of the wiring pattern and the conductive layer.

15. The multilayer wiring substrate of claim 1, wherein the insulating layer includes a plurality of insulating layers stacked along the vertical direction, and
wherein the plurality of insulating layers are bonded to each other by a thermocompression method.

16. The multilayer wiring substrate of claim 1, wherein the wiring pattern and the conductive layer are formed integrally.

17. The multilayer wiring substrate of claim 1, wherein the bonding layer includes a first layer disposed in the first region and a second layer disposed in the second region,
wherein a thermal diffusivity of the second layer is greater than that of the first layer.

18. The multilayer wiring substrate of claim 17, wherein a heat capacity of the second layer is greater than a heat capacity of the first layer.

19. The multilayer wiring substrate of claim 17, wherein a density of the second layer is greater than a density of the first layer.

20. The multilayer wiring substrate of claim 17, wherein a resistance of the second layer is less than a resistance of the first layer.
